(19) United States
(12) Patent Application Publication
(10) Pub. No.: US 2022/0006441 A1
(43) Pub. Date: Jan. 6, 2022

(54) ELECTRO ACOUSTIC RESONATOR AND RF FILTER

(71) Applicant: RF360 EUROPE GMBH, Munchen (DE)

(72) Inventors: Gholamreza DADGAR JAVID, Munchen (DE); Christian HUCK, Munchen (DE)

(21) Appl. No.: 17/288,437

(22) PCT Filed: Nov. 19, 2019
(86) PCT No.: PCT/EP2019/081803

§ 371 Date: Apr. 23, 2021

(30) Foreign Application Priority Data
Nov. 28, 2018 (DE) 10 2018 130 144.8

(51) Int. Cl. H03H 9/13; H03H 9/17; H03H 9/54

(52) U.S. Cl. CPC H03H 9/13; H03H 9/54; H03H 9/17

(57) ABSTRACT

An electro acoustic resonator compatible with thin piezoelectric films and providing additional degrees of freedom is provided. The resonator comprises an IDT section with two bus bars (ES,BB) and electrode fingers (ES,EF). The IDT section is slanted by an angle α through shearing and rotated as a whole by an angle β with respect to the piezoelectric axis (PA).

The present invention refers to electro acoustic resonators that may be combined to establish RF filters that may be used in wireless communication devices.

Electro acoustic resonators can be electrically combined, e.g. in a ladder-type like circuit topology or in a lattice-type like circuit topology, to establish RF filters such as bandpass filters or band rejection filters. Such filters can be used in wireless communication devices. The trend towards miniaturization demands for smaller spatial dimensions. The trend towards a higher number of wireless functions results in stricter specifications that have to be complied with. Thus, there is a general problem of providing resonators for filters with good electric and acoustic performance that comply with specifications.

Conventional electro acoustic resonators can comprise an acoustic track in which acoustic waves can propagate. An electrode structure is arranged on a piezoelectric material and converts—due to the piezoelectric effect—between electromagnetic RF signals and acoustic RF signals that propagate in the acoustic track. Typically, it is desired to have a single acoustic wave mode. However, in real transducers spurious modes can be excited that deteriorate the acoustic and electric performance of the resonator and, correspondingly, of the RF filter.

From US 2013/0051588 A1 electro acoustic transducers and corresponding resonators with reduced losses and with a reduced transversal emission of acoustic energy and improved performance and an improved suppression of transversal modes are known.

However, it was found that the technical measures disclosed therein may have reduced effects in a new type of electro acoustic resonator that use the piezoelectric material provided as a thin film.

Thus, it is desired to have an improved electro acoustic resonator that provides RF filters with good electrical and acoustic performance and that is compatible with a thin film piezoelectric material.

Further, a corresponding transducer should have suppressed or eliminated spurious modes, reduced acoustic losses, and improved dielectric strength to prevent electrostatic discharge and improved power durability.

Further, it is desired to have additional degrees of freedom in designing resonators and filters. Specifically, it is desired to obtain steeper pass band or rejection band flanks.

To that end, an electro acoustic resonator according to the independent claim is provided. Dependent claims provide preferred embodiments and preferred filters.

The electro acoustic resonator comprises a piezoelectric material with a piezoelectric axis, a propagation direction and an electrode structure. The electrode structure has an IDT section (IDT=Inter Digital Transducer) with two bus bars and electrode fingers. The electrode fingers extend in a direction normal to the propagation direction. The IDT section is slanted. Further, the slanted IDT section is rotated with respect to the piezoelectric axis.

In the present resonator the piezoelectric material and the electrode structure establish an acoustic track. The acoustic track is the area of the resonator that is provided for the propagation of the acoustic waves. The direction of the propagation of the acoustic waves establishes the longitudinal direction x of the acoustic track and of the resonator. The slanting of the IDT segment means that the resonator—compared to a non-slanted resonator—is sheared such that the electrode fingers maintain their direction extension. However, the transversal position of the electrode fingers depend on the longitudinal position of the finger. In contrast, the bus bars have a direction of extension that is rotated with respect to the longitudinal direction x. The bus bars can be arranged at the transversal side flanks of the acoustic track. The transversal direction is essentially orthogonal to the longitudinal direction in the plane essentially defined by the surface of the piezoelectric material.

It is to be noted that “x” denotes a position along the longitudinal direction. “y” denotes a position along the transversal direction orthogonal to the longitudinal direction.

In addition to rotation of the extension of the bus bars that is due to the slanting the corresponding slanted IDT section is additionally rotated—by an angle β—with respect to the piezoelectric axis.

The normal direction of the electrode fingers maintain determining the direction of propagation x along the longitudinal direction because this direction is defined by the orientation of the fingers as the direction normal to the fingers' extension. However, the rotation with respect to the piezoelectric axis results in a non-orthogonal relation of the fingers and the piezoelectric axis.

It is possible that this rotation reduces the electro acoustic coupling coefficient.

A reduced electro acoustic coupling coefficient can reduce the pole-zero distance of the resonator.

A reduced pole-zero distance can result in a reduced band width or a reduced width of a rejection band if such resonators are connected to establish a band pass filter or a band rejection filter, respectively.

Further, a reduced pole-zero distance can result in steeper flanks of pass bands or rejection bands.

Thus, a new degree of freedom is obtained for shaping a band pass filter's or a band rejection filter's flanks.

The rotation angle β can be equal to or between −45° and −5° or equal to or between −5° and 5° or equal to or between 5° and 45°: −45°≤β≤−5° or −5°≤β≤5° or 5°≤β≤45°.

It is possible that the bus bars extend along a slanting direction rotated by an angle α1 with respect to the propagation direction. The slanting direction can be rotated by an angle larger than or equal to −15° and smaller than or equal to 15°: −15°≤α1≤15°.

It is possible that the resonator further comprises a second IDT section with two bus bars and electrode fingers and/or more IDT sections with their corresponding fingers and bus bars.

It is to be noted that in the case of a resonator having more than one IDT sections bus bars of different sections can be electrically connected or not. A one port resonator can have a first group of connected bus bars and a second group of connected bus bars. The two groups correspond—electrically—to the resonators electric connections.

In case of a two port resonator or a multi port resonator—e.g. a DMS resonator—more than two groups of electrically isolated bus bars can exist.

It is possible that the bus bars of the second IDT section extend along a slanting direction rotated by an angle α2 with respect to the propagation direction. The slanting direction can be rotated by an angle larger than or equal to −15° and smaller than or equal to 15°: −15°≤α1≤15° . Thus, the rotation of the second segment can be in a direction opposite to the rotation of the first IDT section.

It is possible that the bus bars of the second IDT section extend are parallel to the propagation direction.

Then, the second IDT section is a non slanted section the bus bars of which are rotated with respect to the piezoelectric axis. The rotation angle is β.

A resonator comprising 2 slanted sections (generally with different slanting angles) is denoted as a broken slanted resonator.

It is possible that the resonator is a rotated zigzag slanted resonator.

A zigzag slanted transducer comprises iteratively repeated segments with generally different slanting angles having possibly alternating signs (positive and negative slanting angles).

It is possible that the resonator has a symmetric zigzag pattern.

A symmetry of the resonator can be a translational symmetry, a reflection symmetry with respect to a mirror plane or with respect to a point symmetry.

It is possible that the resonator comprises two slanted IDT sections and an impedance element arranged—in a transversal direction—next to the IDT sections.

The slanting typically demands for extra area consumption of the piezoelectric material. However, a filter element with small spatial dimension can be obtained instead if a location, e.g. in the “V” shaped area next to a resonator with at least two segments, is used for placing additional circuit elements. Such circuit elements can be passive elements such as inductance elements, impedance elements, resistance elements, signal lines, phase lines, etc. and circuits comprising such elements. E.g. Impedance matching circuit can consist of or comprise such elements.

It is possible that the electro acoustic resonator is selected from a SAW resonator (SAW=surface acoustic wave), a TC-SAW resonator (TC=temperature compensated), a GBAW resonator (GBAW=guided bulk acoustic wave) and a TF-SAW resonator (TF=thin film).

A TC-SAW resonator comprises a temperature compensation material above or below the electrode structure. The stiffness parameters of the material of the temperature compensation structure is chosen such that a temperature induced drift of characteristic frequencies of the resonator is reduced or eliminated. It is possible that a corresponding temperature compensation structure comprises an oxide such as a silicon oxide such as SiO₂.

A GBAW resonator comprises a waveguiding structure arranged above and/or below the electrode structure such that the propagating waves are propagating at the interface between the piezoelectric material and a corresponding waveguiding layer.

A TF-SAW resonator utilizes a piezoelectric material provided as a thin film. The thin film is provided utilizing thin film layer deposition techniques such as CVD (chemical vapor deposition), PVD (physical vapor deposition), sputtering, MBE (molecular beam epitaxy) and the like.

It is possible that the thin film piezoelectric material is arranged on a carrier substrate.

It is possible that the electrode structure is selected from an unweighted transducer, an apodized transducer, a slanted transducer, a broken slanted transducer and a zigzag slanted transducer. In an unweighted transducer each pair of electrode fingers essentially contribute the same amount to the conversion between electromagnetic RF signals and acoustic RF signals. To that end, the overlap along the transversal direction of neighboring electrode fingers of opposite polarity can be equal along the longitudinal direction of the acoustic track.

In contrast, a weighted transducer provides different contributions to the overall excitation of acoustic waves for different pairs of neighboring electrode fingers of opposite polarity. To that end, the transversal overlap of the neighboring fingers can differ along the longitudinal direction. Such a weighted transducer can be an apodized transducer. An apodized transducer can be a sine weighted transducer or a cosine weighted transducer.

A slanted transducer has an angle between the direction of extension of the bus bars and the electrode fingers that deviates from 90°. Typically, the electrode fingers are oriented orthogonal to the piezoelectric axis of the piezoelectric material. The electrode fingers are typically also orthogonal to the direction of the propagation of the acoustic waves of the wanted main acoustic mode. Thus, the extension of the bus bars in a slanted transducer is not parallel to the direction of propagation of acoustic waves, i.e. to the longitudinal direction.

It was found that slanting or apodizing resonators can effectively reduce unwanted transversal modes even in a TF-SAW resonator.

Further, it was found that diffraction effects in the gap region of a resonator have a more severe impact on the resonator's performance than in unweighted resonators because the interaction between acoustic waves and the gap region is intensified in corresponding geometries. Thus, the counterintuitive approach of providing a homogenous transversal velocity profile that can correspond to a homogeneous acoustic impedance even in the gap region minimizes unwanted acoustic effects in the gap region.

Thus, improved electro acoustic resonators that are compatible with thin film piezoelectric materials can be obtained with the above-described measures.

A broken slanted transducer has segments along the acoustic track with different slanting angles. Thus, a broken slanted transducer has at least two segments. It is possible that in one segment the slanting angle is 0°. Such a segment corresponds to a segment of a conventional, non-slanted resonator.

A zigzag slanted transducer comprises iteratively repeated segments with generally different slanting angles having possibly alternating signs. Positive and negative slanting angles are possible.

It is possible that the electro acoustic resonator is selected from a one-port resonator, a two-port resonator, a multi port resonator and a DMS resonator (DMS=dual mode SAW).

A one-port resonator has only one port to be connected to an external circuit environment. A two-port resonator has two ports to be connected to an external circuit environment. One of the two ports can be an input port for receiving electromagnetic RF signals. The respective other port can be an output port for providing electromagnetic RF signals to an external circuit environment.

A DMS resonator can be established as a one-port resonator or as a two-port resonator. In a DMS resonator more than one acoustic main modes can propagate. A DMS resonator can comprise a first IDT (IDT=interdigital transducer) and a second IDT.

The resonator can have a single transducer or a plurality of transducers. The one or more transducers of the resonator can be arranged between elements of an acoustic reflector, e.g. elements of Bragg reflectors.

One or more transducers can be weighted, apodized, slanted, broken slanted or zigzag slanted. However, it is also possible that several transducers are slanted such that a plurality of transducers in the acoustic track establish a broken slanted or zigzag slanted excitation structure.

The IDTs of resonators can be arranged between reflector structures of the resonator.

It is possible to use the described resonator in an RF filter.

Correspondingly, it is possible that an RF filter comprises an electro acoustic resonator as described above.

The RF filter can be a bandpass filter or a band rejection filter and can be used in a frontend circuit of a wireless communication device. It is possible that the RF filter has a ladder-type like filter topology or a lattice-type like filter topology.

In a ladder-type like filter topology one or more series resonators are electrically connected in series in a signal line between an input port and an output port. One or more parallel resonators can be arranged in one or more shunt paths electrically connecting the signal line to ground.

A lattice-type like filter topology can have an input port and an output port. The input port can comprise a first input terminal and a second input terminal. The output port can comprise a first output terminal and a second output terminal. A lattice-type like filter topology is obtained if one resonator electrically connects the first input terminal to the second output terminal. A signal crossing of signals propagating via a first resonator and a second resonator is obtained.

It is possible that an RF filter further comprises a non slanted and/or a—with respect to the piezoelectric axis—non rotated resonator.

Then, a frequency dependent attenuation can be obtained by combining conventional resonators (with non rotated and slanted IDT sections) that allow a wide band width with resonators as described above to locally increase a flank steepness.

The RF filter can be a transmission filter or a reception filter of a multiplexer, e.g. of a duplexer.

The above resonator reduces unwanted acoustic modes and provides additional degrees of freedom to a designer such that a resonator that is compatible with good electric and acoustic properties and thin film piezoelectric materials is obtained.

Central aspects of the provided resonator and details of preferred embodiments are shown and explained the accompanying schematic figures. For simplicity reasons some figures do not show the acoustic reflectors or further elements that are necessary for forming a resonator.

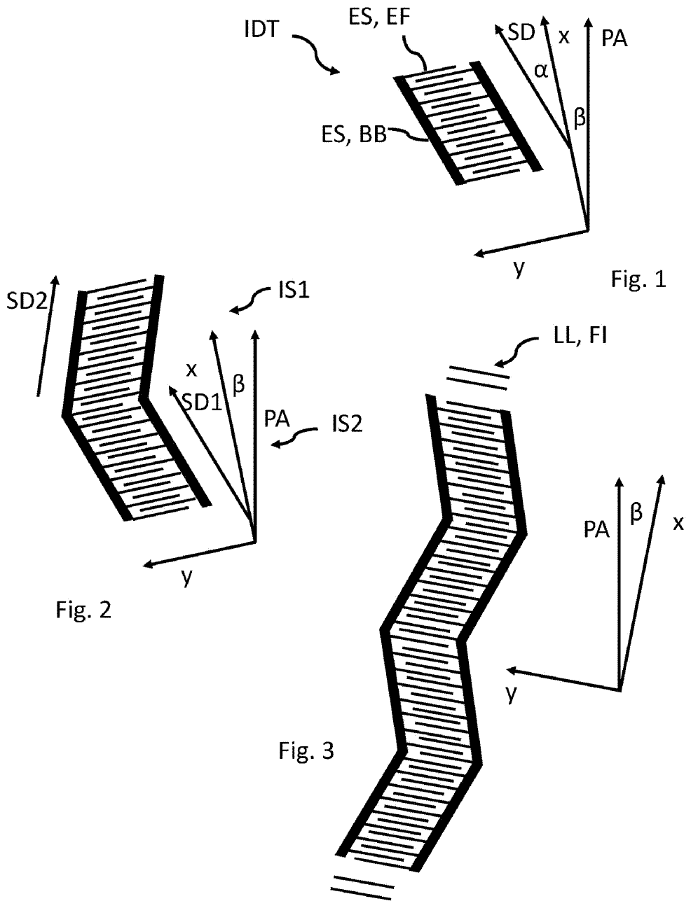

FIG. 1 shows a slanted IDT section that is rotated with respect to the piezoelectric axis.

FIG. 2 shows a broken slanted resonator that is rotated.

FIG. 3 shows a rotated zigzag slanted IDT.

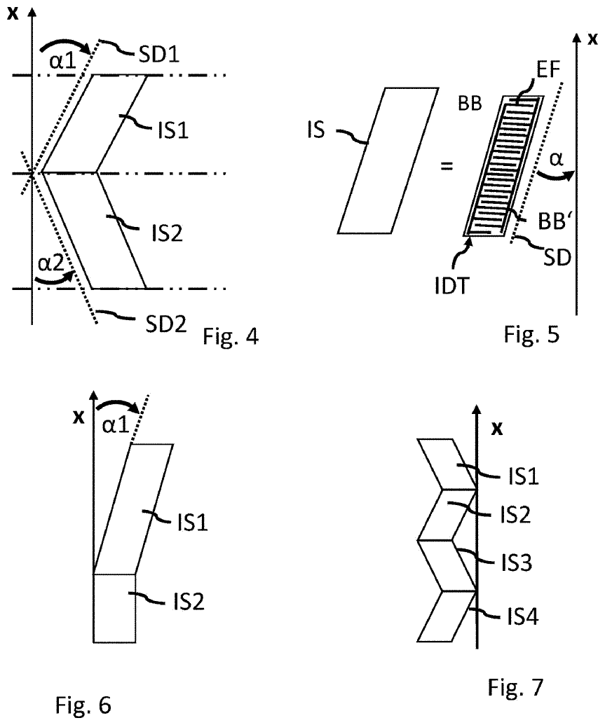

FIG. 4 shows a schematic depiction of a first embodiment of the electroacoustic resonator with two IDT sections enclosing different angles with the x-axis.

FIG. 5 shows more details of the IDT section that is depicted only schematically in FIG. 4.

FIG. 6 shows another embodiment of two IDT sections enclosing different angles with the x-axis.

FIG. 7 shows four subsequent IDT sections that form a zigzag arrangement.

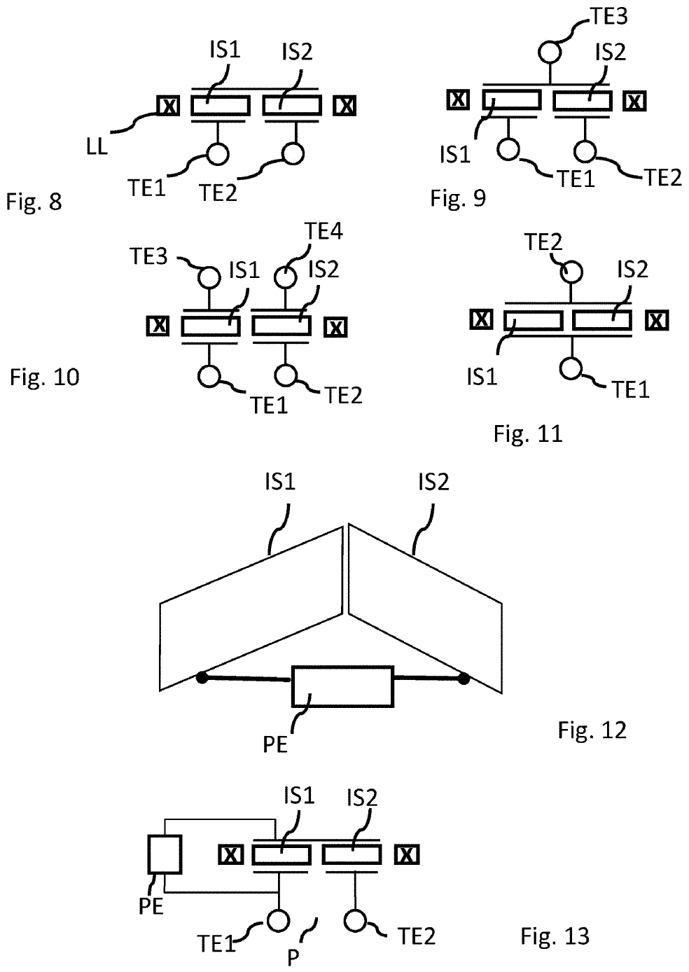

FIGS. 8 to 11 show schematically different ways of circuiting two subsequent IDT sections that are slanted relative to each other.

FIGS. 12 and 13 show two subsequent IDT sections that are connected via different passive elements.

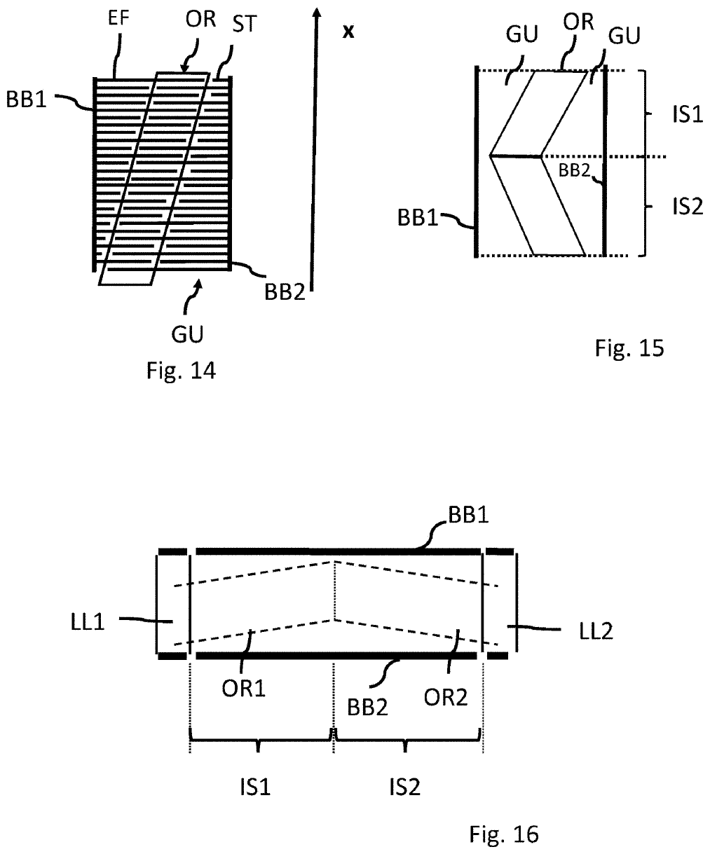

FIG. 14 shows a slanted IDT section with bus bars oriented in parallel to the wave propagation direction (x-axis) and resulting in stub fingers of different length.

FIG. 15 shows an arrangement of two IDT sections slanted to the x-axis with different angles but with two common bus bars that are oriented in parallel to the wave propagation direction (x-axis) with stub fingers of varying length.

FIG. 16 shows two slanted IDT sections of a one-port resonator arranged between two reflectors.

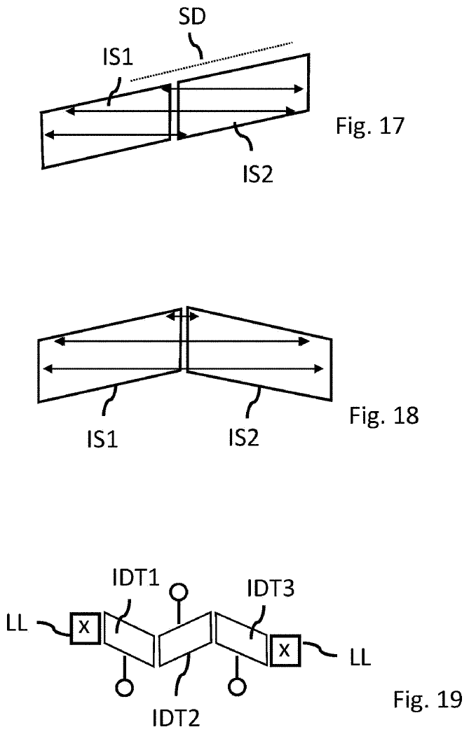

FIG. 17 shows schematically two longitudinally acoustically coupled subsequent IDT sections that are slanted with the same slanting angle.

FIG. 18 shows schematically two longitudinally acoustically coupled subsequent IDT sections that are slanted with different slanting angles.

FIG. 19 shows a possible layout of a DMS resonator.

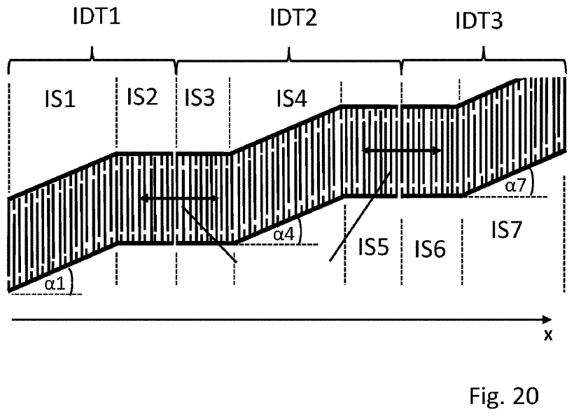

FIG. 20 shows another embodiment of a DMS filter with three IDTs where each IDT comprises a number of different slanted IDT sections within the same IDT.

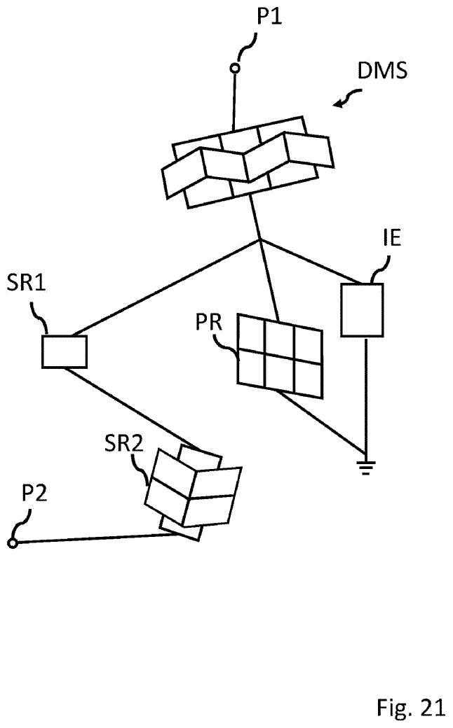

FIG. 21 shows a possible ladder type like circuit topology connected to a DMS resonator.

FIG. 1 shows a slanted interdigital transducer IDT that is rotated with respect to the piezoelectric axis PA. The transducer IDT can be arranged on a piezoelectric material. The material has the piezoelectric axis PA.

The direction of extension y of the electrode fingers EF is denoted as transversal direction. The longitudinal direction x is within the plane according to which the electrode structure is oriented and orthogonal to the transversal direction. The longitudinal direction is also the direction of propagation of the acoustic waves when the resonator is active.

The slanting of the resonator reduces unwanted wave modes even when the resonator is a TF-SAW resonator. It is to be noted that the slanting does not change the orientation of the electrode fingers or the direction of propagation.

The rotation of the resonator with respect to the piezoelectric axis results in a rotated electrode finger direction, in a rotated direction of propagation and in a reduced electro acoustic coupling factor.

Generally, angles denoted by a refer to slanting angles due to a shearing of the IDT section. Angles denoted β refer to the rotation of the electrode structure of the IDT section as a whole.

FIG. 2 shows a combination of two slanted IDT sections IS1, IS2, called broken slanted IDT. The two IDT sections have different slanting angles defined by their slanting directions SD1, SD2 or different directions of the slanting. However, all electrode fingers are parallel and both sections underlie the same rotation with the rotation angle β relative to the piezoelectric axis PA.

The two sections IS1, IS2 are symmetric with respect to t mirror plane parallel to the finger direction.

FIG. 3 shows a rotated zigzag slanted inter digital transducer. Two groups of slanted sections exist. The two groups have a translation symmetry. In each group the sections have a mirror plane symmetry. Each section is subject to a slanting according to one of two slanting directions. The whole resonator is subject to a common rotation with the rotation angle β. An acoustic reflector LL having reflector fingers FI is indicated.

FIG. 4 shows a simple embodiment of the invention comprising two adjacent IDT sections IS1 and IS2 in a simplified depiction. A first IDT section IS1 extends along a first slanting direction SD1 that includes an angle α1 to the x-axis where the x-axis is the propagation direction of the acoustic wave. The directly adjacent second IDT section IS2 includes a slanting angle α2 to the x-axis where aα1 s not equal to α2. The second IDT section IS2 extends parallel to the second slanting direction SD2. For clarity reason each slanting direction is depicted adjacent to the respective resonator section IS. The slanting angles α may have absolute values between 0 and 30 degrees. An optimized slanting angle α is chosen in dependence on the piezoelectric material and the desired properties of the SAW device that the depicted arrangement is a part of.

FIG. 5 shows an exemplary IDT section IS depicting most important parts thereof. The IDT section IS comprises two bus bars BB, BB′ from which electrode fingers EF are extending to interdigitate alternatingly. The electrode fingers EF are oriented normal to the x-axis and form an overlap region that extends parallel to a slanting direction SD. A slanting angle α is measured between the x-axis and the slanting direction SD. The bus bars BB may be oriented in parallel to the slanting direction or alternatively deviate from such a parallel orientation. Not shown are stub fingers that are present in a preferred IDT section design in the non-overlap region that is arranged between the overlap region and a respective bus bar. If the orientation of the bus bar BB deviates from the orientation of a slanting direction a non-overlap region yields having a triangular shape (shown in FIG. 14 or 15 for example). Preferably the overlap between two adjacent electrode fingers EF is the same along the whole length of the IDT section IS and more preferably is the same in all IDT sections IS.

FIG. 6 shows another embodiment of how two adjacent IDT sections IS1, IS2 can be arranged relative to one another. In this broken slanted resonator the first IDT section IS1 includes a slanting angle α1 to the x-axis while the second IDT section IS2 extends parallel to the x-axis such that the slanting angle α of the second IDT section IS2 is 0. Further, the length of the depicted two IDT sections is different but may also be the same.

FIG. 7 shows a zigzag arrangement of subsequent IDT sections IS. Depicted are four IDT sections IS1 to IS4, but a zigzag arrangement can generally be achieved with three or more IDT sections. Each IDT section IS comprises a slanting angle α that is enclosed between the slanting direction of the respective IDT section and the x-axis. Each IDT section may have a different slanting angle. Each IDT section may have a length that may be equal for all IDT sections. Moreover, the length may be different for two adjacent IDT sections or may be different for all of the IDT sections.

Each of the IDT sections includes a slanting angle α to the x-axis where the slanting angles of two subsequent IDT sections IS are different. As shown in FIG. 7 a zigzag arrangement of IDT sections may extend as a whole in parallel to the x-axis but it is also possible that the zigzag topology extends with an angle relative to the x-axis. This means that not only IDT sections are slanted but also the total zigzag arrangement can be slanted against the x-axis.

Moreover, despite a symmetric arrangement of IDT sections is preferred the arrangement may also have no symmetry element.

As already explained, different IDT sections IS may be electrically connected or not. However, in all cases different IDT sections within one track belong to the same resonator.

FIGS. 8 to 11 show exemplarily in respective block diagrams four different possibilities for electrically connecting two adjacent IDT sections IS that are arranged within an acoustic track between two reflectors LL. The figure is drawn schematically only and does not show any geometrical detail such as a slanting angle of at least one of the IDT sections IS1, IS2.

FIG. 8 shows two adjacent IDT sections IS1, IS2 within one acoustic track. One bus bar is common to both IDT sections. The other bus bar is divided so that each IDT section has its own bus bar section separated from the bus bar section of the other IDT section. The resulting structure is an electrical series connection of first and second IDT section IS1, IS2 between a first and a second terminal TE1, TE2.

FIG. 9 shows two IDT sections having the same arrangement of bus bars like shown in FIG. 8 but with a different circuiting. Each bus bar or bus bar section of the IDT sections has its own electrical terminal TE which allows to circuit both IDT sections IS1, IS2 in parallel or in series.

FIG. 10 shows an arrangement wherein each of the two depicted IDT sections IS1, IS2 has its own bus bars on both sides of the interdigital transducer such that no galvanic contact exists between the two IDT sections. Notwithstanding that, the four terminals of the two IDT sections allow an arbitrary mutual circuiting of the two IDT sections.

FIG. 11 shows the simplest arrangement of two adjacent IDT sections that share both bus bars. A first and a second bus bar are common to both IDT sections IS1, IS2. Each bus bar is coupled to a respective terminal TE on a respective side of the arrangement.

The arrangements shown in FIGS. 8 to 11 can represent one-port resonators while FIG. 10 can also be circuited as a two-port resonator.

Each two subsequent IDT sections IS1, IS2 with different slanting angles α form a V-shaped arrangement. There is some space between the inner legs of the V-shaped arrangement for arranging therein an element like a passive element PE.

FIG. 12 shows a very general depiction of such an arrangement that uses the free space between the two legs of the V-shaped arrangement. A passive element PE may be interconnected to one or both IDT sections or to any other element of the SAW device or of the circuit the SAW device is arranged in. The passive element may be capacitance or an inductance, for example, or a combination of them, e.g. to form a matching circuit.

FIG. 13 shows an arrangement with two IDT sections circuited in series between a first and a second terminal TE1, TE2. Here, the passive element—or more generally: an element or a circuit, e.g. a matching circuit—interconnects a first bus bar connected to terminal TE1 and the opposite bus bar. But as explained above any other interconnection to any element of the SAW device is possible too. The passive element PE may be used as a matching element of the SAW device. Such a connection of matching circuit elements is also possible for all circuits, e.g. the variants in FIGS. 9 to 11.

An arrangement where the free space between the two legs of the V-shaped arrangement is used by placing any element of the SAW device or a circuit there results in a better exploitation of the available space. Then it is possible to reduce the area of the SAW device because the space for the additional element like the passive element PE is saved at another location on the surface of the substrate.

FIG. 14 shows an IDT section IS comprising one interdigital transducer. The transducer comprises a first and a second bus bar BB1, BB2. Electrode fingers EF are extending from each bus bar to interdigitate in an overlap region OR. Between the tip of an electrode finger EF and the bus bar that is not connected to this electrode finger EF, a stub finger ST is arranged. Thereby the non-overlap region between the overlap region and a respective bus bar BB is filled with stub fingers or the non-overlapping section of the electrode fingers EF.

A further feature of the depicted interdigital transducer is the orientation of the overlap region OR that is parallel to the slanting direction of this IDT section. Contrary to the formerly described arrangements, the bus bars are not parallel to the slanting direction. Hence, the overlap region OR is orientated along the slanting direction LA and LA is slanted against the linearly extending bus bars. This means that each non-overlap region of the IDT section is a trapezoid or a triangle. Then the stub fingers ST have necessarily various lengths to completely fill the non-overlap region GU. However, one of the middle axes may be oriented in parallel to the x-axis such that besides the unavoidable transversal gap and optionally short stub fingers ST no non-overlap region GU is formed adjacent to this IDT section IS.

FIG. 15 shows the arrangement of two such IDT sections IS1, IS2, each having a different slanting angle α relative to the x-axis. Both adjacent IDT sections share their bus bars BB1, BB2 so that each common bus bar has a linear and straight extension that may be arranged parallel to the x-axis but not parallel to the slanting direction of any of the two IDT sections. Here too, the schematically depicted non-overlap region GU between the overlap region OR and the opposing bus bar BB is filled with stub fingers ST.

According to a variant the non-overlap region GU may be covered with a continuous metal layer that can be formed by structuring one or more bus bars accordingly. Then, a respective bus bar section has triangular shape.

Resonators formed by at least one IDT section are arranged within an acoustic track between two reflectors LL. As only one slanted resonator is present in the acoustic track the SAW device forms a one-port SAW resonator.

FIG. 16 is another depiction of a one-port resonator with two slanted IDT sections to form a V-shaped arrangement. Here too, each bus bar BB1, BB2 is common to both IDT sections IS2, IS2, is extending linearly and may be arranged in parallel to the x-axis or not. This means that trapezoidal, e.g. triangular, non-overlapping regions are formed between the overlap regions OR1, OR2 and the neighboured bus bar BB. In FIG. 16, the overlap region OR is depicted to be the area between the two dotted lines. At the same time the dotted line is the location of the finger gap between the tip of an overlapping electrode finger and the opposing stub finger. It is preferred that the transversal gap is as small as possible. With the present available technology, a small gap of 100 nm to 500 nm can be achieved.

On both sides of the shown resonator a respective acoustic reflector LL1, LL2 is placed to enclose the acoustic energy there between. The dotted lines extend into part of the respective reflector which means that the reflector fingers of each acoustic reflector LL are partly interdigitating despite being electrically shorted. Alternatively, the gaps need not extend into the reflector such that each reflector finger is connected to both reflector bus bars.

From FIG. 16 it can further be seen that the aperture that is defined by the transversal length of a finger overlap is shifted or varying along the x-axis from finger to finger in y-direction. But the shift is small enough that the apertures that have the greatest shift or variation relative to the outermost aperture at the beginning or the end of the resonator still have a mutual overlap when looking parallel to the x-axis. This means that the coupling between different ends of a IDT section is still high enough to allow suitable operation of the resonator.

FIGS. 17 and 18 show two adjacent IDT sections IS1, IS2 that may form part of a DMS filter. While the IDT sections of FIG. 17 are both slanted with the same slanting angle such that they share the same slanting direction SD in FIG. 18 the two IDT sections are arranged with different slanting angles in the broken slanted design according to the invention. The depicted arrows symbolize the longitudinal acoustic coupling between two IDT sections. Depending on slanting angles in FIG. 18 there are certainly slanting angles which yield higher coupling, compared to non-broken structures.

In all embodiments each two subsequent IDT sections IS1, IS2 with different slanting angles α form a V-shaped arrangement. Thereby some free space between the inner legs of the V-shaped arrangement is spared allowing to arrange therein a circuit element like a passive element PE.

FIG. 19 shows a schematic block diagram of a DMS filter comprising three interdigital transducers IDT1 to IDT3, each interdigital transducer IDT comprising an IDT section IS as described above such that the DMS filter has a broken slanted design. Each of the slanting angles of the IDT sections may be different. Slanting angles α1 and α2 may alternate according to the relation α1=−α2 to form a regular symmetric zigzag arrangement of IDT section. A reflector LL each is arranged at both lateral (longitudinal) ends of the acoustic track of the DMS filter.

However, the interdigital transducers which form resonators of the DMS structure are not restricted to comprise only one IDT section each. Hence, each resonator may comprise two or more IDT sections that are slanted with a respective slanting angle where different IDT sections may have different slanting angles.

A DMS filter may have more than three interdigital transducers that are usually alternatingly connected to a first and a second terminal.

A passive element may be interconnected to one or both IDT sections or to any other element of the SAW device or of the circuit the SAW device is arranged in. The passive element may be a capacitance or an inductance, for example. Also, it can be an element having an inductance value and ac capacitance value. Specifically, it may be a combination of elements, e.g. a circuit, e.g. a matching circuit. It may be formed by a structured metallization on top of the free substrate surface. Alternatively a discrete passive element can be arranged on the substrate between each two legs of a V. The passive element may connected to one leg, to two legs or is just arranged between the legs to only use the free space without being connected to a bus bar of the V or of another IDT section. If connected to a resonator the passive element may be used as a matching element of the SAW device.

An arrangement where the free space between the two legs of the V-shaped arrangement is used by placing any element of the SAW device or a circuit there results in a better exploitation of the available chip area. Then it is possible to reduce the area of the SAW device because the space for the additional element like the passive element is saved at another location on the surface of the substrate.

FIG. 20 shows a further embodiment of a DMS filter comprising at least three interdigital transducers IDT1, IDT2 and IDT3. The first interdigital transducer IDT1 comprises two IDT sections IS1, IS2 each having a respective slanting angle α1, α2 (which may equal zero and, hence, its representation in the figure is omitted) relative to the longitudinal direction. In this embodiment the first slanting angle α1 is greater than 0 and greater than the second slanting angle α2 which may be zero as shown in the figure or not.

The second interdigital transducer IDT2 comprises three IDT sections IS3 to IS5, each IDT section IS including a respective slanting angle relative to the longitudinal direction. The third IDT section IS3 is arranged with a low slanting angle preferably of zero like the second IDT section IS2. This allows maximum longitudinal acoustic coupling between second and third IDT section and hence maximum coupling between first and second interdigital transducers IDT1 and IDT2. The slanting angle α4 of the fourth IDT section IS4 which is the second IDT section of the second transducer IDT2 and which is arranged in the middle of the second interdigital transducer IDT2, is greater than the slanting angle α3 (also not explicitly shown) of the third IDT section IS3 and greater than the slanting angle α5 of the fifth IDT section IS5.

The third interdigital transducer IDT3 on the right side of the figure comprises two IDT sections IS6 and IS7 each including a respective slanting angle α6, α7 (also not explicitly shown) to the longitudinal direction. The slanting angle α7 of the outermost right IDT section IS7 is greater than the slanting angle α6 of the sixth IDT section IS6.

As a consequence, the outermost IDT sections of each interdigital transducer IDT that are facing each other may have a small slanting angle or a zero slanting angle. It is also possible that the slanting angles of each two outermost IDT sections that are directly adjacent to each other are equal but not zero. Hence, the two adjacent outermost IDT sections between first and second or second and third interdigital transducer IDT extend in parallel or almost in parallel. In the figure, the slanting angles of outermost IDT sections IS2, IS3, IS5 and IS6 are depicted to be zero but this is not a necessary feature of the invention as explained above.

By this arrangement the longitudinal acoustic coupling between the adjacent interdigital transducers is at a maximum as indicated in the figure with the double-sided arrows.

If the two adjacent outermost IDT sections would be inclined relative to each other, the coupling would be reduced. Hence, the arrangement of the DMS filter depicted in FIG. 20 combines the advantage of a slanted orientation for transversal mode suppression with the advantage of a high longitudinal acoustic coupling between the outermost IDT sections of two adjacent resonators. In this embodiment each present slanting angle α may be different from the other used slanting angles. But it is preferred to design a DMS filter with a high symmetry relative to a middle transducer or a middle IDT section. A symmetric arrangement of transducers may be achieved if IDT sections that have the same symmetric element are equal in their absolute values of slanting angle and equal in length.

The IDT sections of the DMS filter as shown in FIG. 20, for example, may have different lengths. It is preferred that the outermost IDT sections with the lowest slanting angles have a smaller length than the other IDT sections but they need to be long enough to ensure optimum longitudinal acoustic coupling between adjacent IDTs. Further, it is possible to divide a resonator in more than the depicted two or three IDT sections such that an according interdigital transducer may comprise four or more IDT sections. Short IDTs may have only one IDT section.

All possible variations can be used to increase the degrees of freedom when designing a specific DMS filter. The optimization of the filter can be made towards better filter performance or towards better use of chip area. Usually a trade-off has to be made which can be optimized by the possible variations.

Further variations of the SAW filter are possible which are per se known from the art and can advantageously improve the SAW device. The mode that propagates in the acoustic track of the SAW filter can be formed as a pure piston mode by adding mode-forming features to the design of the electrode fingers. Such features may comprise additional mass load at the finger tips or a greater finger width at the tips thereof. Different gap lengths are possible to reduce unwanted transversal modes. It is preferred that the transversal gap is as small as possible. With the present available technology, a small gap of 100 nm to 500 nm can be achieved.

In a slanted IDT section the aperture that is defined by the transversal length of a finger overlap is shifted along the longitudinal direction from finger to finger in y-direction. But the shift is small enough that the apertures that have the greatest shift or variation relative to the outermost aperture at the beginning or the end of the resonator still have a mutual overlap when looking parallel to the longitudinal direction. This means that the coupling between different ends of an IDT section is still high enough to allow suitable operation of the resonator.

FIG. 21 shows a possible ladder type like circuit topology of an RF filter. The RF filter has a first port P1 and a second port P2. The first port P1 can be an input port for receiving RF signals from an external circuit environment. The second port can be an output port for providing filtered RF signals to an external circuit environment.

In the signal path between the two ports P1, P2 a DMS resonator DMS, a first series resonator SR1 and a second series resonator SR2 are electrically connected in series. Two parallel shunt paths connect the signal path to ground. In one shunt path a parallel resonator PR is connected. In the other shunt path an impedance element IE is connected. The impedance element can comprise acoustically inactive IDT structures to establish a capacitance element. The capacitance element can be used to improve a pass band flank.

The DMS resonator DMS comprises four slanted and rotated IDT sections.

The first series SR1 resonator comprises conventional (i.e. non-rotated, non-slanted) IDT sections.

The second series resonator SR2 comprises cascaded (2×2) rotated and slanted IDT sections.

The parallel resonator PR comprises cascaded (2×3) rotated and slanted IDT section.

The degree of the series cascading is two. The degree of the parallel cascading is 3.

Thus, 2×3=6 IDT sections are contained in the parallel resonator PR.

### LIST OF REFERENCE SIGNS

β: rotation angle with respect to the piezoelectric axis

BB, BB1, BB2: bus bar

SD, SD1, SD2: slanting direction

IDT, IDT1, . . . : interdigital transducer

IS, IS1, IS2, . . . : IDT section

P1, P2: first, second filter port

α: angle between x-axis and slanting direction

LL: acoustic reflector

ES: electrode structure

GU: non-overlap region

TE: terminal of IDT section

ST: stub fingers

EF: electrode finger

FI: reflector finger

DMS: dual mode SAW filter

OR: overlap region

P: filter port

PA: piezoelectric axis

PE: passive element

x: longitudinal direction, direction of propagation of SAW

y: transversal direction

1. An electro acoustic resonator, comprising:
a piezoelectric material with a piezoelectric axis;
a propagation direction; and
an electrode structure having an IDT section with two bus bars and electrode fingers, wherein:
the electrode fingers extend normal to the propagation direction,
the IDT section is slanted, and
the slanted IDT section is rotated with respect to the piezoelectric axis.

2. The electro acoustic resonator of claim 1, wherein the bus bars extend along a slanting direction rotated by an angle α1 with respect to the propagation direction, wherein −15°>α1≤15°.

3. The electro acoustic resonator of claim 1, further comprising a second IDT section with two bus bars and electrode fingers.

4. The electro acoustic resonator of claim 1, wherein the bus bars of the second IDT section;
extend along a slanting direction rotated by an angle α2 with respect to the propagation direction and −15°≤α2≤155°; or
are parallel to the propagation direction.

5. The electro acoustic resonator of claim 1, wherein the electro acoustic resonator is a rotated zigzag slanted resonator.

6. The electro acoustic resonator of claim 1, further comprising a symmetric zigzag pattern.

7. The electro acoustic resonator of claim 1, further comprising at least two slanted IDT sections and an impedance element arranged in a transversal direction next to the at least two slanted IDT sections.

8. The electro acoustic resonator of claim 1, wherein the electro acoustic resonator includes a SAW resonator, a TC-SAW resonator, a GBAW resonator, or a TF-SAW resonator.

9. The electro acoustic resonator of claim 1, wherein the electrode structure is selected from an unweighted transducer, an apodized transducer, a slanted transducer, a broken slanted transducer, a zigzag slanted transducer.

10. The electro acoustic resonator of claim 1, wherein the electro acoustic resonator includes a one-port resonator, a two-port resonator, or a DMS resonator.

11. The electro acoustic resonator of claim 1, wherein the electro acoustic resonator is part of an electro acoustic filter.

12. The electro acoustic resonator of claim 1, wherein the electro acoustic filter includes a ladder type like topology or a lattice type like topology.

13. The electro acoustic resonator of claim 1, wherein the electro acoustic filter includes a non slated and/or a—with respect to the piezoelectric axis—non rotated resonator.
